(19) United States
(12) Patent Application Publication
(10) Pub. No.: US 2026/0348496 A1
(43) Pub. Date: Nov. 5, 2026

(54) FLANGE, FLANGED JOINT, VACUUM AND/OR REACTION CHAMBER, AND SYSTEM FOR THERMAL LASER EPITAXY

(71) Applicant: Max-Planck-Gesellschaft zur Förderung der Wissenschaften e.V., München (DE)

(72) Inventors: Wolfgang BRAUN, Bietigheim-Bissingen (DE); Johannes Arnoldus BOSCHKER, Stuttgart (DE)

(21) Appl. No.: 19/488,394

(22) PCT Filed: Jun. 6, 2024
(86) PCT No.: PCT/EP2024/065638

§ 371 Date: Jan. 30, 2026

(30) Foreign Application Priority Data
Jun. 7, 2023 (DE) 10 2023 115 004.9

(51) Int. Cl. F16L 23/032; C30B 23/06; F16L 23/20

(52) U.S. Cl. CPC F16L 23/032; C30B 23/066; F16L 23/20

(57) ABSTRACT

The invention relates to a flange (10) composed of an aluminum alloy, wherein the flange (10) is arranged or can be arranged in a sealed manner at an opening (104) in a chamber wall (102) of a vacuum and/or reaction chamber (100), wherein the flange (10) further has a peripheral and planar sealing surface (20) for sealing the opening (104) of the vacuum and/or reaction chamber (100) with respect to the environment, said sealing surface being adjoined by a cutting edge (30) for a knife-edge seal (40). Furthermore, the invention relates to a flange connection (50) having a first flange element (52), a second flange element (54), a sealing ring (60) and a clamping apparatus (70), wherein the first flange element (52) and the second flange element (54) each have a cutting edge (30) for a knife-edge seal (40), wherein the sealing ring (60) consists of a softer material than the cutting edges (30) and can be arranged between the first flange element (52) and the second flange element (54), and the first flange element (52) and the second flange element (54) can be pressed against one another by the clamping apparatus (70) in order to seal the flange connection (50) so that the cutting edge (30) of the first flange element (52) and the cutting edge (30) of the second flange element (54) press into the sealing ring (60) from opposite sides. The invention further relates to a vacuum and/or reaction chamber (100) comprising a chamber wall (102) and an opening (104) in the chamber wall (102), wherein the vacuum and/or reaction chamber (100) further has such a flange (10) for the opening (104), wherein the flange (10) is arranged in a sealed manner at the opening (104). The invention further relates to a system for thermal laser epitaxy (TLE) comprising at least one vacuum and/or reaction chamber (100) of such a kind, wherein the vacuum and/or reaction chamber (100) has a chamber wall (102) having one or more openings (104) at each of which a flange (10) is arranged.

The invention relates to a flange composed of an aluminum alloy, wherein the flange is arranged or can be arranged in a sealed manner at an opening in a chamber wall of a vacuum and/or reaction chamber, wherein the flange further has a peripheral and planar sealing surface for sealing the opening of the vacuum and/or reaction chamber with respect to the environment, said sealing surface being adjoined by a cutting edge for a knife-edge seal. Furthermore, the invention relates to a flange connection having a first flange element, a second flange element, a sealing ring and a clamping apparatus, wherein the first flange element and the second flange element each have a cutting edge for a knife-edge seal, wherein the sealing ring consists of a softer material than the cutting edges and can be arranged between the first flange element and the second flange element, and the first flange element and the second flange element can be pressed against one another by the clamping apparatus in order to seal the flange connection so that the cutting edge of the first flange element and the cutting edge of the second flange element press into the sealing ring from opposite sides. The invention further relates to a vacuum and/or reaction chamber comprising a chamber wall and an opening in the chamber wall, wherein the vacuum and/or reaction chamber further has such a flange for the opening, wherein the flange is arranged in a sealed manner at the opening. The invention further relates to a system for thermal laser epitaxy (TLE) comprising at least one vacuum and/or reaction chamber of such a kind, wherein the vacuum and/or reaction chamber has a chamber wall having one or more openings at each of which a flange is arranged.

Vacuum and/or reaction chambers are widely used in modern technology, for example, to provide a space or a volume that is sealed off with respect to the environment. A controllable reaction atmosphere can then in particular be provided in these vacuum and/or reaction chambers, wherein properties of the reaction atmosphere, such as composition and pressure, can be set as desired over wide ranges.

A material that is often used for such vacuum and/or reaction chambers is steel. For some areas of use, it has, however, been found that steel is not the best choice, for example, if a high thermal conductivity of the material of the vacuum and/or reaction chamber is advantageous. One example of such an application is thermal laser epitaxy (TLE) in which source material provided in the volume of the vacuum and/or reaction chamber is thermally vaporized and/or sublimated by high-intensity laser radiation below the plasma threshold. The vaporized and/or sublimated material is usually used to deposit a high-purity layer on a substrate, in other words to vaporize the substrate.

If the laser beam is in this respect incident on the chamber wall of the vacuum and/or reaction chamber, accidentally or, for example, after reflection at the source material, a high energy input into the material of the vacuum and/or reaction chamber can be the result. By using a material with a high thermal conductivity compared to steel, a local heating of the chamber wall up to physical damage can be avoided or at least significantly reduced. For example, aluminum alloys are suitable materials.

At the same time, it is necessary to enable access to the interior of the vacuum and/or reaction chamber, in the above example in particular for a coupling in of the laser beam and for a provision of the source material and the substrate to be vaporized. Flanges or flange connections are suitable means of providing the necessary access to the interior of the vacuum and/or reaction chamber at openings in the chamber wall, on the one hand, but simultaneously enabling a sealing of this opening with respect to the environment. Since these flanges or flange connections could also be accidentally impinged by laser radiation as part of the vacuum and/or reaction chamber, they can preferably also be made of an aluminum alloy.

As already explained above, high-purity layers can be vapor deposited onto a substrate in a TLE system. To achieve this, the reaction atmosphere present in the interior of the vacuum and/or reaction chamber must also meet the highest standards. This can inter alia be achieved in that the vacuum and/or reaction chamber is heated in a so-called bake-out process prior to the vaporization. In this respect, it is necessary for a sealed flange to have a high leak-tightness before, during and in particular also after this heating since otherwise environmental air can enter the vacuum and/or reaction chamber again.

In summary, based on known vacuum and/or reaction chambers and flanges or flange connections, the object thus results of providing an improved flange, an improved flange connection, an improved vacuum and/or reaction chamber and an improved TLE system that have been further developed compared to the prior art. In particular, it is the object of the present invention to provide an improved flange, an improved flange connection, an improved vacuum and/or reaction chamber and an improved TLE system, in which a high leak-tightness, preferably the highest leak-tightness, of the flange is or remains guaranteed before, during and after a heating in the course of a bake-out process.

This above object is satisfied by the independent claims. In particular, the object is satisfied by a flange according to claim 1, by a flange connection according to claim 13, by a vacuum and/or reaction chamber according to claim 16 and by a TLE system according to claim 19. Further features result from the dependent claims, from the description, and from the drawings. In this respect, features and advantages that are described in relation to the flange according to the invention also apply with respect to a flange connection according to the invention, with respect to a vacuum and/or reaction chamber according to the invention or with respect to a TLE system according to the invention and vice versa in each case, insofar as technically sensible and possible.

According to a first aspect of the invention, the object is satisfied by a flange composed of an aluminum alloy, wherein the flange is arranged or can be arranged in a sealed manner at an opening in a chamber wall of a vacuum and/or reaction chamber, wherein the flange further has a peripheral and planar sealing surface for sealing the opening of the vacuum and/or reaction chamber with respect to the environment, said sealing surface being adjoined by a cutting edge for a knife-edge seal, wherein an inner side surface of the cutting edge, said inner side surface adjoining the sealing surface, encloses an angle of 110° with the sealing surface.

The material for the flange according to the invention comprises an aluminum alloy. Compared to steel, the vast majority of the possible aluminum alloys have a higher thermal conductivity. Aluminum alloys can be selected with many different properties, wherein particularly hard, heat-stable and low-outgassing variants of aluminum alloys are preferred for the use as flanges of vacuum and/or reaction chambers.

The flange according to the invention is provided for a use at or with a vacuum and/or reaction chamber, in particular a vacuum and/or reaction chamber of a TLE system. For this purpose, the flange according to the invention can be arranged at an opening in a chamber wall of the vacuum and/or reaction chamber. With this arrangement, attention must in particular be paid to a tight transition between the material of the chamber wall and the material of the flange. A bonded connection of the flange to the vacuum and/or reaction chamber by welding has proven to be particularly suitable in this respect. Alternatively, the flange can also be formed in one piece with the vacuum and/or reaction chamber from the outset and can be monolithically manufactured therewith, for example by a chip-forming process.

The flange arranged at the opening of the vacuum and/or reaction chamber thus substantially extends this opening, often perpendicular to the chamber wall. To maintain the sealability of the interior of the vacuum and/or reaction chamber with respect to the environment, it is thus necessary to also equip the flange with a possibility for a sealed closing. According to the invention, this takes place via the provision of a sealing surface that is provided peripherally around the opening, which is virtually extended by the flange, in the chamber wall at the flange. The sealing surface is planar overall per se, wherein a normal of this plane of the sealing surface is preferably oriented transversely, in particular at a right angle, to the opening. Overall, the flange according to the invention is prepared for a knife-edge seal. This is in particular reflected in that a cutting edge for this knife-edge seal is arranged outwardly adjoining the sealing surface.

In the case of knife-edge seals, the flange and the corresponding counterpart, often also a flange or a cover, usually have such sealing surfaces and cutting edges between which a sealing ring, usually composed of a softer metal, is inserted. The cutting edges press into the sealing ring, whereby the sealing effect of the knife-edge seal substantially results. Knife-edge seals can, for example, enable particularly low pressures of up to 10⁻¹² hPa in the interior of the vacuum and/or reaction chamber.

As essential to the invention, provision is now made that an inner side surface of the cutting edge, said inner side surface adjoining the sealing surface, encloses an angle of 110° with the sealing surface. Angle specifications in this application in this respect always refer to the specified angle and a range around this angle that can be achieved with reasonable accuracy in the manufacture of the flange. For knife-edge seals in accordance with the ISO 3669:2020(E) standard, values of up to 92° are possible for this angle. Due to the flatter transition from the planar sealing surface to the inner side surface of the cutting edge, a higher force compared to the standardized flange is required for the flange according to the invention in order to achieve the same sealing effect. This can be explained in that, with a small enclosed angle and thus a steeper transition between the sealing surface and the inner side surface of the cutting edge, the cutting edge presses more easily into the sealing ring even with smaller forces. However, this can easily be compensated for by an increase in the sealing force.

At the same time, however, it has been found that the flatter design according to the invention of the transition between the sealing surface and the inner side surface retains its high leak-tightness even on a heating of the vacuum and/or reaction chamber, in particular during a bake-out process. This is presumably due to a higher proportion of elastic energy, which is stored here by the compression of the seal, and is in contrast to the behavior of the knife-edge seals with steeper transitions between the sealing surface and the cutting edge, as is provided in accordance with the above-mentioned standard.

In summary, a possibility is thus provided by the flange according to the invention of closing an opening in a wall of a vacuum and/or reaction chamber, in particular a vacuum and/or reaction chamber of a TLE system, such that a high leak-tightness of the flange is achieved before, during and after a heating in the course of a bake-out process.

Furthermore, with the flange according to the invention, provision can be made that the flange consists of the aluminum alloy. In this design, the flange is thus made completely of the aluminum alloy and does not have other materials. The advantages described above when using an aluminum alloy as the material for the flange according to the invention can thereby be made possible even better and in particular covering the entire flange.

Furthermore, the flange according to the invention can be characterized in that an outer side surface of the cutting edge adjoins the inner side surface, wherein the inner side surface and the outer side surface enclose an angle of 90°. In other words, the outer side surface is inclined by 20° with respect to the sealing surface. An angle of 90° at the tip of the cutting edge has proven to be particularly suitable for producing a cutting edge, which presses sufficiently into a correspondingly present sealing ring, despite the flatter transition from the sealing surface to the inner side surface. The leak-tightness that can be provided according to the invention before, during and after a heating process can thus be made possible even better.

The flange according to the invention can also be further developed such that the inner side surface and the outer side surface adjoin one another with a rounded connection edge, wherein a radius of a rounding of the connection edge amounts to between 0.1 mm and 0.2 mm, preferably amounts to 0.2 mm. With a too sharp connection edge of the two side surfaces of the cutting edge, it can occur that the cutting edge plastically deforms the material of the correspondingly present sealing ring too much, whereby too little elastic deformation remains in the connection in order, during and after the bake-out process, to elastically, i.e. reversibly, absorb possible deformations occurring due to a different thermal expansion and, as a result, to obtain the sealing effect. Due to a rounded connection edge with a radius of the rounding of between 0.1 mm and 0.2 mm, preferably of 0.2 mm, this too small proportion of the elastic deformation can be avoided or at least significantly restricted.

Furthermore, the flange according to the invention can be configured such that the inner side surface and/or the outer side surface of the cutting edge surrounds/surround the opening in a cone-like manner. In particular for circular openings, it is advantageous to also provide the flange, and in particular the elements provided for the knife-edge seal at the flange, with a rotational symmetry. This can be made possible in a particularly simple manner by side surfaces of the cutting edge that are formed in a cone-like manner. Cone-like in the sense of the invention in this respect means for the side surfaces that they are configured as the lateral surface of a respective truncated cone, wherein the truncated cone assumed for the inner side surface points inwards, i.e. in the direction of the remaining flange, with the end of the smaller diameter. Conversely, the truncated cone assumed for the outer side surface points outwards, i.e. away from the flange.

According to a further embodiment of the flange according to the invention, it can be characterized in that carbon black is at least partly applied to the cutting edge. Carbon black is substantially pure carbon and has lubricating properties without presenting a risk of outgassing that is associated with conventional greases and oils, for example. By applying carbon black to the cutting edge, undesirable stresses between the flange and the correspondingly present sealing ring, which are often caused by unavoidable tilting of these components relative to one another, can be counteracted. For the application, the carbon black can preferably be suspended in high-purity propanol that then evaporates after the application. A particularly uniform application of the carbon black can thereby be ensured.

Furthermore, the flange according to the invention can be further developed such that the carbon black is applied to the outer side surface and the inner side surface is free of carbon black. According to the geometry of the flange according to the invention, the inner side surface of the cutting edge is closer to the opening in the chamber wall of the vacuum and/or reaction chamber, and correspondingly the outer side surface is further away from it. By applying the carbon black only to the outer side surface of the cutting edge, the advantages described above with respect to an improved lubrication between the flange and the sealing ring, in particular during their deformation during the sealing process, can thus be made possible, on the one hand, but a risk of a contamination of the inner space of the vacuum and/or reaction chamber with carbon black can simultaneously be significantly reduced.

Also, with the flange according to the invention, provision can further be made that the aluminum alloy used for the flange has a proportion of zinc of 0.15% or less, preferably of 0.10% or less. Some components of aluminum alloys, and zinc must in particular be emphasized in this respect, are not suitable for a use in particular for high and ultra-high vacuum applications since they are highly reactive and in particular have a high vapor pressure. When pumping out the vacuum and/or reaction chamber, these components would outgas from the alloy and would thus prevent or at least significantly delay the reaching of the desired vacuum. Due to a limitation of the zinc content of the aluminum alloy used to 0.15% or less, in particular 0.10% or less, this disadvantage can at least with respect to zinc be reduced to such an extent that it is no longer a decisive factor.

According to a further embodiment of the flange according to the invention, it can be characterized in that the aluminum alloy used for the flange has a Brinell hardness of 100 HBW or greater. The hardness of the flange according to the invention is in particular decisive for the durability, in other words for the time interval with which maintenance intervals can be planned. Furthermore, the hardness in particular has a decisive influence on the stability of the cutting edge of the knife-edge seal that, as stated above, when the flange preferably completely consists of the aluminum alloy, likewise consists of said aluminum alloy. A Brinell hardness of 100 HBW or greater has proven to be preferable in order to ensure a particularly good durability of the entire flange and in particular a high stability of the cutting edge.

Furthermore, the Brinell hardness of 100 HBW or greater has the advantage of reducing the likelihood or severity of accidental damage to the cutting edge when handling such flanges and assembling the vacuum chambers or reaction chambers composed thereof.

Furthermore, provision can be made with the flange according to the invention that the aluminum alloy used for the flange is suitable for a use at temperatures of 140 °C or higher, preferably 200 °C or higher. As has already been stated multiple times above, in particular when used in a TLE system, the vacuum and/or reaction chamber comprising the flange according to the invention is usually subjected to a heating in the course of a bake-out process. Such bake-out processes can take place over a longer period of time, usually several days, depending on the application. A suitability of the aluminum alloy used for the flange at temperatures of 140 °C or higher, preferably 200 °C or higher, has proven to be sufficient to withstand the necessary heating processes without damage.

According to a first alternative embodiment, provision can further be made with the flange according to the invention that the aluminum alloy used for the flange is an Al5xxx alloy. Al5xxx alloys are characterized by medium to high strengths and in particular by a high corrosion resistance. They are furthermore easy to weld and can easily be cold-formed, i.e. processed by rolling and forging. Overall, these Al5xxx alloys, for example the standardized alloy EN AW-5083, are good materials in order to manufacture a flange according to the invention therefrom. In particular, flanges that are to be bonded to a vacuum and/or reaction chamber by welding can preferably comprise or consist of such an AL5xxx alloy.

In a second alternative embodiment, the flange according to the invention can be characterized in that the aluminum alloy used for the flange has the following components in addition to aluminum:
Si: a maximum of 0.30%
Fe: a maximum of 0.40%
Cu: 5.8%-6.8%
Mn: 0.20%-0.40%
Mg: a maximum of 0.10%
Cr: a maximum of 0.05%
Zn: a maximum of 0.10%
Ti: 0.02%-0.10%
Further components: a maximum of 0.15%, of which individual components: a maximum of 0.05%

One such aluminum alloy is, for example, marketed by the company Bikar Metalle under the brand name Formodal® BM-400. Due to its special composition, this aluminum alloy is in particular characterized in that it combines the properties already highlighted as advantageous above. It has a zinc content of a maximum of 0.10%, a Brinell hardness of 130 HBW and is suitable for a long-term use at temperatures of up to 200 °C. All of the advantages associated with these properties above can thus be made possible when this aluminum alloy is used as a component of the flange according to the invention. An aluminum alloy as listed above thus represents a particularly suitable aluminum alloy in order with it, or even completely from it, to produce a flange according to the invention or preferably even complete vacuum and/or reaction chambers.

According to a second aspect of the invention, the object is satisfied by a flange connection having a first flange element, a second flange element, a sealing ring and a clamping apparatus, wherein the first flange element and the second flange element each have a cutting edge for a knife-edge seal, wherein the sealing ring consists of a softer material than the cutting edges and can be arranged between the first flange element and the second flange element, and the first flange element and the second flange element can be pressed against one another by the clamping apparatus in order to seal the flange connection so that the cutting edge of the first flange element and the cutting edge of the second flange element press into the sealing ring from opposite sides. The flange connection according to the invention is characterized in that the first flange element and/or the second flange element is/are configured as a flange according to the first aspect of the invention.

The flange connection according to the invention in accordance with the second aspect of the invention has, as flange elements, at least one, preferably two, flanges according to the first aspect of the invention. All the features and advantages that have been described in detail above with respect to a flange according to the first aspect of the invention can thus also be made possible by a flange connection according to the second aspect of the invention.

For the assembly of the flange connection according to the invention, the softer sealing ring is inserted between the flange elements and they are then pressed against one another by the clamping apparatus. Screws can, for example, be used as the clamping apparatus and engage through correspondingly present bores in the flange elements. Alternatively or additionally, other clamping apparatus are also conceivable, for example, peripheral chain elements or tension belts.

Due to the clamping apparatus, such large forces are generated that the cutting edges press into the sealing ring from oppositely disposed sides. To make this possible, the material of the sealing ring is selected such that it is softer than the material of the cutting edges, preferably than the material of the entire flange elements. A particularly good sealing, which in particular also enables a generation of a high vacuum in the vacuum and/or reaction chamber, can thereby be made possible.

In particular, if both flange elements are configured as flanges according to the first aspect, a sealed connection between these vacuum and/or reaction chambers can be produced by the arrangement or arrangement capability of the flanges at openings of the respective vacuum and/or reaction chamber. Due to the use of aluminum alloys for the flange elements, in particular a use in a TLE system is favored.

Furthermore, a particularly good temperature resistance of the sealing of the flange connection, in particular, for example, with respect to the behavior during a bake-out process, can be made possible by the design of the flange elements as flanges according to the invention, and thus in particular of those sections which are used for forming the knife-edge seal, such as the sealing surfaces and the cutting edge.

Furthermore, provision can be made with the flange connection according to the invention that the sealing ring consists of an aluminum alloy, preferably of EN AW-1050A. As described above, at least one, preferably both flange elements are made of an aluminum alloy. Due to the use of an aluminum alloy also as the material for the sealing ring, it can be made possible that an expansion behavior of the components involved in the knife-edge seal, i.e. in particular of the two flange elements and the sealing ring, is the same or at least very similar. A consistently high sealing even with large temperature changes can thereby be made possible. The aluminum alloy designated with the standard number EN AW-1050A has proven to be particularly suitable as a material for sealing rings since it is softer compared to many other aluminum alloys.

Furthermore, the flange connection according to the invention can be characterized in that the first flange element is configured as a flange according to the first aspect of the invention, and wherein the second flange element is configured as a cover that is configured analogously to a flange according to the first aspect of the invention. A flange according to the first aspect of the invention is arranged in a sealed manner at an opening in a chamber wall of a vacuum and/or reaction chamber or can at least be arranged at such an opening. A cover, on the other hand, is a component that is provided for a sealed covering and closing of that end of a flange which carries the knife-edge seal. For this purpose, the cover likewise has the necessary components for the knife-edge seal, i.e. in particular a peripheral sealing surface and a cutting edge, but a continuous material plate is located therebetween. When used in a flange connection according to the invention, the flange according to the invention, which forms the first flange element, is thus closed by the cover, which forms the second flange element, and is sealed by the correspondingly formed knife-edge seal.

A “continuous material plate” within the meaning of the invention in particular includes material plates in which sealed elements, such as windows or feedthroughs, in particular for electrical connections or for fluids, are arranged.

A cover configured analogously to a flange according to the first aspect of the invention is to be understood within the meaning of the invention such that all the features that are not associated with the opening of the vacuum and/or reaction chamber, i.e. in particular the material used and the design and treatment of the cutting edge, can also be realized in the cover. In terms of the sealing, in particular at high temperatures such as during a bake-out process, due to a flange connection with a cover, the same features and benefits can thus be made possible that can also be made possible by a flange connection with two flanges according to the invention.

According to a third aspect of the invention, the object is satisfied by a vacuum and/or reaction chamber having a chamber wall and an opening in the chamber wall, wherein the vacuum and/or reaction chamber further has a flange for the opening, wherein the flange is arranged in a sealed manner at the opening, wherein the flange is configured according to the first aspect of the invention. All the features and advantages that have been described in detail above with respect to a flange according to the first aspect of the invention can thus also be made possible by a vacuum and/or reaction chamber according to the third aspect of the invention.

It can in particular also be provided here that the flange of the vacuum and/or reaction chamber is part of a flange connection according to the invention in accordance with the second aspect of the invention.

In particular, the vacuum and/or reaction chamber according to the invention can be characterized in that the vacuum and/or reaction chamber and the flange are manufactured in one piece and monolithically. In other words, the vacuum and/or reaction chamber and the flange are already arranged adjacent to one another during the manufacture and do not need to be fixed to one another. One possibility, for example, represents a manufacture in a chip-forming process, in particular milling, from a common metal block. A particularly stable and in particular particularly tight arrangement of the flange at the vacuum and/or reaction chamber can thereby be made possible.

Further, in the vacuum and/or reaction chamber according to the invention, it can also be provided that the vacuum and/or reaction chamber has two or more openings in the chamber wall at each of which a flange according to the first aspect of the invention is arranged. In this way, the features and advantages described with respect to a flange according to the invention in accordance with the first aspect can be made possible at a plurality of openings in the chamber wall of the vacuum and/or reaction chamber. Preferably, the vacuum and/or reaction chamber has such a flange according to the invention in accordance with the first aspect of the invention at each of its openings in the chamber wall. In this embodiment, the vacuum and/or reaction chamber can further preferably also be manufactured in one piece and monolithically with the present flanges according to the invention.

According to a fourth aspect of the invention, the object is satisfied by a system for thermal laser epitaxy (TLE) comprising at least one vacuum and/or reaction chamber, wherein the vacuum and/or reaction chamber has a chamber wall having one or more openings at each of which a flange is arranged, wherein the vacuum and/or reaction chamber is configured according to the third aspect of the invention. The vacuum and/or reaction chamber according to the third aspect of the invention has one or more flanges according to the first aspect of the invention that can in turn be parts of flange connections according to the invention in accordance with the second aspect of the invention. All the features and advantages that have been described in detail above with respect to a vacuum and/or reaction chamber according to the third aspect of the invention, with respect to a flange according to the first aspect of the invention and with respect to a flange connection according to the second aspect of the invention can thus also be made possible by a TLE system according to the fourth aspect of the invention.

The invention will be described in the following with reference to Figures. The Figures show in detail:

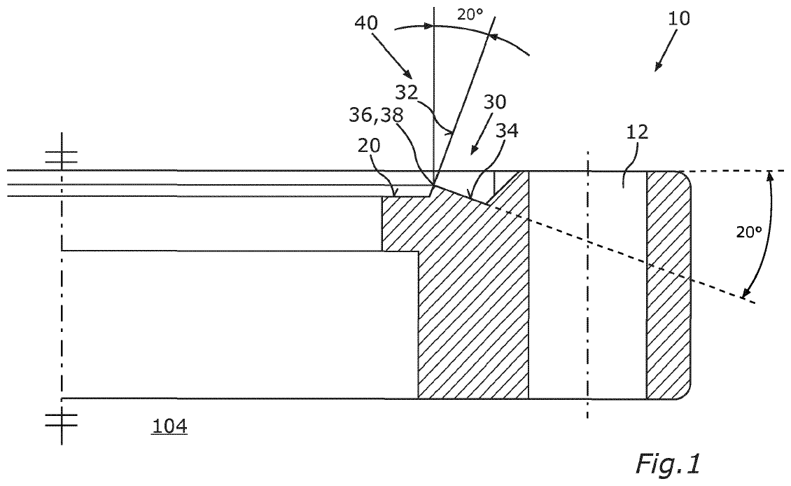

FIG. 1 a sectional view of a part of a flange according to the invention;

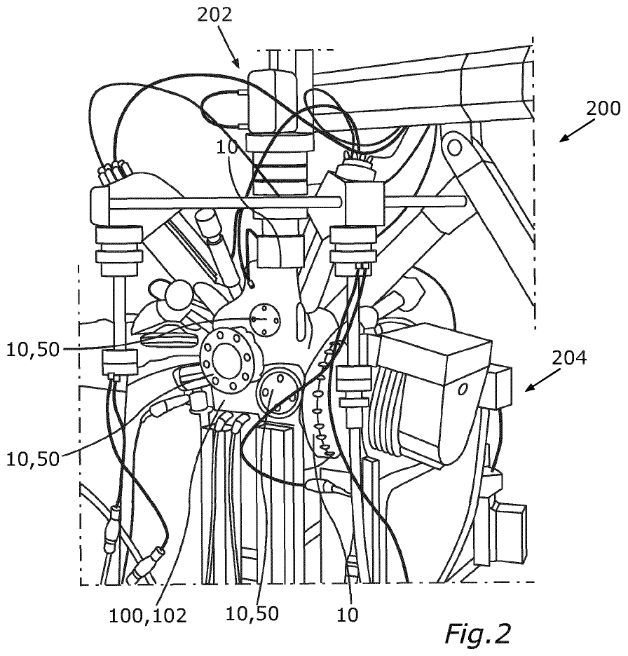

FIG. 2 a TLE system according to the invention with a vacuum and/or reaction chamber according to the invention; and

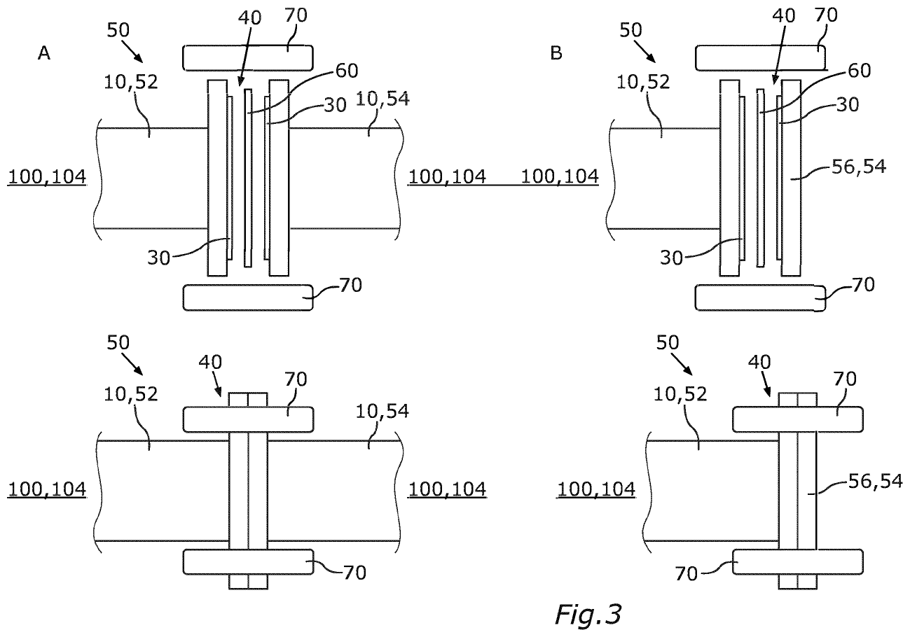

FIG. 3 two flange connections according to the invention.

FIG. 1 shows, in a part view, a section through a possible embodiment of a flange 10 according to the invention. According to the invention, it is provided that the flange can be arranged or is already arranged at an opening 104 in a chamber wall 102 of a vacuum and/or reaction chamber 100 (cf. FIG. 2).

For a sealing of the opening 104, the flange 10 according to the invention has precautions for providing a knife-edge seal 40. In particular, a sealing surface 20 is present that peripherally surrounds the opening 104. A cutting edge 30, which adjoins the sealing surface 20 at the radially outer side, is provided for the actual knife-edge seal 40. As shown, the sealing surface 20 and an inner side surface 32 enclose an angle of 90°+20°, i.e. of 110°, drawn at an elongated line for a better overview. This embodiment enables a constant leak-tightness even in the case of a heating of the vacuum and/or reaction chamber 100, and thus of the flange 10, that is, for example, performed in the course of a bake-out process.

As a further component of the cutting edge 30, the outer side surface 34 is also shown that, as illustrated, can preferably be oriented at an angle of 20° with respect to the plane of the sealing surface 20. The angle between the inner side surface 32 and the outer side surface 34 thereby results as 90°. In particular in the case of a circular opening 104, the two side surfaces 32, 34 are preferably shaped in a cone-like manner. At their connection edge 36, provision is further preferably made that it is rounded, in particular with a radius of the corresponding rounding 38 between 0.1 mm and 0.2 mm.

Carbon black can also be applied to the cutting edge 30, preferably exclusively to the outer side surface 34 of the cutting edge 30, in order to avoid or at least significantly reduce unnecessary and undesirable mechanical stresses between the flange 10 and a sealing ring accordingly used as the sealing material.

The flange 10 according to the invention comprises, and preferably consists of, an aluminum alloy as the material. One example of a possible aluminum alloy is an AI 5xxx alloy that, for example, has particularly good welding properties.

Further preferred properties of the aluminum alloy used are a zinc content of less than 0.15%, a Brinell hardness of 100 HBW or greater, and a suitability for a long-term use at temperatures up to 140 °C or higher. One aluminum alloy that has all these properties is, for example, Formodal® BM-400 from the company Bikar Metalle.

In FIG. 2, a vacuum and/or reaction chamber 100 is shown as it is used in a TLE system 200. A plurality flanges 10, which are each formed in one piece and monolithically with the vacuum and/or reaction chamber 100, are clearly visible. The flanges 10 in turn are partly components of flange connections 50 according to the invention. A laser system 202 is flanged to one of the flanges 10 and a gas system 204 is flanged to a further flange 10. Due to the use of the flanges 10 according to the invention, an increased safety against accidental damage caused by an unintentionally occurring radiation of the laser of the laser system 202 can in particular be provided by the higher thermal conductivity compared to steel. At the same time, the shape of the knife-edge seal 40 of the flanges 10 according to the invention makes it possible that an improved leak-tightness can also be made possible before, during and after heating processes, for example for bake-out processes. A purity of the atmosphere that is present in the vacuum and/or reaction chamber 100 and that is decisive for the quality of the vaporizations produced in the TLE system 200 can thereby be made possible in an improved manner.

In FIG. 3, two possible embodiments of flange connections 50 according to the invention are shown that each comprise two flange elements 52, 54. In the left-hand column, labeled “A” in FIG. 3, both flange elements 52, 54 are configured as flanges 10 according to the invention (cf. FIG. 1). In the right-hand column, labeled “B” in FIG. 3, the first flange element 52 is likewise configured as a flange 10 according to the invention, whereas the second flange element 54 is configured as a cover 56. For both kinds of flange connections 50, a schematic exploded representation is shown in the top row; the respective flange connection 50 is shown closed in the bottom row. In the following, the flange connections 50 shown in “A” and “B” are described together, with the differences between the two embodiments being discussed.

As already stated above, a flange connection 50 according to the invention has two flange elements 52, 54 that each have a cutting edge 30 for a knife-edge seal 40. In particular, at least one of the two flange elements 52, 54, preferably both, is configured as a flange 10 according to the invention.

However, even if only one of the two flange elements 52, 54 is configured as a flange 10 according to the invention, in all the embodiments of the flange connection 50 according to the invention, the corresponding flange elements 52, 54 are nevertheless configured such that they together form an effective knife-edge seal 40. If, as shown in “B”, a cover 56 is used as the second flange element 54, said cover can preferably be configured analogously to a flange 10 according to the invention.

“Configured analogously” within the meaning of the invention in particular means that all the features that are not associated with the opening 104 of the vacuum and/or reaction chamber 100 (cf. FIG. 2), i.e. in particular the material used for the cover 56 and the design and treatment of its cutting edge 30, can also be realized in the cover 56.

In this case, the flange 10 used as the first flange element 52 and the cover 56 used as the second flange element 54 particularly preferably have the same aluminum alloy as the material; in particular, both components consist of this aluminum alloy. Furthermore, the components of these two flange elements 52, 54 that are necessary for the knife-edge seal 40, in particular the cutting edges 30, are identical in terms of their shape and pre-treatment.

A flange connection 50 according to the invention represents a connection of two flange elements 52, 54 that is sealed by a knife-edge seal 40. For this purpose, as already described, the necessary components, in particular cutting edges 30 but also correspondingly present sealing surfaces 20 (cf. FIG. 1), are provided at the flange elements 52, 54. A sealing ring 60 that consists of a softer material at least than the two cutting edges 30 of the flange elements 52, 56 is inserted between the flange elements 52, 54, see in particular the top row of FIG. 3. Like the two flange elements 52, 54, the sealing ring 60 is preferably made of an aluminum alloy, in particular, for example, of EN AW-1050A. The two flange elements 52, 54 are pressed together by a clamping apparatus 70 to close the flange connection 50, wherein the cutting edges 30 press into the sealing ring 60. This is shown in the bottom row of FIG. 3.

Due to the flange connection 50 shown in “A”, a sealed connection between two vacuum and/or reaction chambers 100 can be provided since the two flanges 10 according to the invention that are used as a flange element 52, 54 are already arranged at openings 104 of these vacuum and/or reaction chambers 100 or can at least be arranged thereat.

Alternatively, a sealed closure of a vacuum and/or reaction chamber 100 can be provided by the flange connection 50 shown in “B”. On the flange 10 according to the invention, which is used as the first flange element 52 and which is in turn arranged at an opening 104 of a vacuum and/or reaction chamber 100 or can at least be arranged thereat, a cover 56 is placed in a sealed manner as the second flange element 54 by the knife-edge seal 40.

The present invention further relates to the following numbered embodiments:
1. A flange (10) composed of an aluminum alloy, wherein the flange (10) is arranged or can be arranged in a sealed manner at an opening (104) in a chamber wall (102) of a vacuum and/or reaction chamber (100), wherein the flange (10) further has a peripheral and planar sealing surface (20) for sealing the opening (104) of the vacuum and/or reaction chamber (100) with respect to the environment, said sealing surface being adjoined by a cutting edge (30) for a knife-edge seal (40).
2. A flange (10) according to embodiment 1,
   wherein an inner side surface (32) of the cutting edge (30), said inner side surface adjoining the sealing surface (20), encloses an angle of 110° with the sealing surface (20).
3. A flange (10) according to one of the embodiments 1 or 2,
   wherein the flange (10) consists of the aluminum alloy.
4. A flange (10) according to any one of the preceding embodiments,
   wherein an outer side surface (34) of the cutting edge (30) adjoins the inner side surface (32), wherein the inner side surface (32) and the outer side surface (34) enclose an angle of 90°.
5. A flange (10) according to embodiment 4,
   wherein the inner side surface (32) and the outer side surface (34) adjoin one another with a rounded connection edge (36), wherein a radius of a rounding (38) of the connection edge (36) amounts to between 0.1 mm and 0.2 mm, preferably amounts to 0.2 mm.
6. A flange (10) according to any one of the preceding embodiments,
   wherein the inner side surface (32) and/or the outer side surface (34) of the cutting edge (30) surrounds/surround the opening (104) in a cone-like manner.
7. A flange (10) according to any one of the preceding embodiments,
   wherein carbon black is at least partly applied to the cutting edge (30).
8. A flange (10) according to embodiment 7,
   wherein the carbon black is applied to the outer side surface (34) and the inner side surface (32) is free of carbon black.
9. A flange (10) according to any one of the preceding embodiments,
   wherein the aluminum alloy used for the flange (10) has a proportion of zinc of 0.15% or less, preferably of 0.10% or less.
10. A flange (10) according to any one of the preceding embodiments,
   wherein the aluminum alloy used for the flange (10) has a Brinell hardness of 100 HBW or greater.
A flange (10) according to any one of the preceding embodiments,
   wherein the aluminum alloy used for the flange (10) is suitable for a use at temperatures of 140 ° C or higher, preferably 200 ° C or higher.
12. A flange (10) according to any one of the preceding embodiments,
   wherein the aluminum alloy used for the flange (10) is an Al5xxx alloy.
13. A flange (10) according to any one of the preceding embodiments 1 to 11,
   wherein the aluminum alloy used for the flange (10) has the following components in addition to aluminum:
      Si: a maximum of 0.30%
      Fe: a maximum of 0.40%
      Cu: 5.8%-6.8%
      Mn: 0.20%-0.40%
      Mg: a maximum of 0.10%
      Cr: a maximum of 0.05%
      Zn: a maximum of 0.10%
      Ti: 0.02%-0.10%
      Further components: a maximum of 0.15%, of which individual components: a maximum of 0.05%
14. A flange connection (50) having a first flange element (52), a second flange element (54), a sealing ring (60) and a clamping apparatus (70),
   wherein the first flange element (52) and the second flange element (54) each have a cutting edge (30) for a knife-edge seal (40),
   wherein the sealing ring (60) consists of a softer material than the cutting edges (30) and can be arranged between the first flange element (52) and the second flange element (54), and the first flange element (52) and the second flange element (54) can be pressed against one another by the clamping apparatus (70) in order to seal the flange connection (50) so that the cutting edge (30) of the first flange element (52) and the cutting edge (30) of the second flange element (54) press into the sealing ring (60) from opposite sides,
   wherein the first flange element (52) and/or the second flange element (54) is/are configured as a flange (10) according to any one of the embodiments 1 to 13.
15. A flange connection (50) according to embodiment 14, wherein the sealing ring (60) consists of an aluminum alloy, preferably of EN AW-1050A.
16. A flange connection (50) according to embodiment 14 or 15,
   wherein the first flange element (52) is configured as a flange (10) according to any one of the embodiments 1 to 12, and wherein the second flange element (54) is configured as a cover (56) that is configured analogously to a flange (10) according to any one of the embodiments 1 to 12,
17. A vacuum and/or reaction chamber (100) comprising a chamber wall (102) and an opening (104) in the chamber wall (102), wherein the vacuum and/or reaction chamber (100) further has a flange (10) for the opening (104), wherein the flange (10) is arranged in a sealed manner at the opening (104), wherein the flange is configured according to any one of the embodiments 1 to 13.
18. A vacuum and/or reaction chamber (100) according to embodiment 17,
   wherein the vacuum and/or reaction chamber (100) and the flange (10) are manufactured in one piece and monolithically.
19. A vacuum and/or reaction chamber (100) according to embodiment 17 or 18,
   wherein the vacuum and/or reaction chamber (100) has two or more openings (104) in the chamber wall (102) at each of which a flange (10) according to any one of the embodiments 1 to 12 is arranged.
20. A system (200) for thermal laser epitaxy (TLE) comprising at least one vacuum and/or reaction chamber (100), wherein the vacuum and/or reaction chamber (100) has a chamber wall (102) having one or more openings (104) at each of which a flange (10) is arranged,
   wherein the vacuum and/or reaction chamber (100) is configured according to any one of the embodiments 17 to 19.

### REFERENCE NUMERALS

10 flange
12 bore
20 sealing surface
30 cutting edge
32 inner side surface
34 outer side surface
36 connection edge
38 rounding
40 knife-edge seal
50 flange connection
52 first flange element
54 second flange element
56 cover
60 sealing ring
70 clamping apparatus
100 vacuum and/or reaction chamber
102 chamber wall
104 opening
200 TLE system
202 laser system
204 gas system

1-18. (canceled)

19. A flange composed of an aluminum alloy, wherein the flange is arranged or can be arranged in a sealed manner at an opening in a chamber wall of a vacuum and/or reaction chamber, wherein the flange further has a peripheral and planar sealing surface for sealing the opening of the vacuum and/or reaction chamber with respect to the environment, said sealing surface being adjoined by a cutting edge for a knife-edge seal,
wherein an inner side surface of the cutting edge, said inner side surface adjoining the sealing surface, encloses an angle of 110° with the sealing surface, wherein the flange consists of the aluminum alloy.

20. The flange according to claim 19,
wherein an outer side surface of the cutting edge adjoins the inner side surface, wherein the inner side surface and the outer side surface enclose an angle of 90°.

21. The flange according to claim 20,
wherein the inner side surface and the outer side surface adjoin one another with a rounded connection edge, wherein a radius of a rounding of the connection edge amounts to between 0.1 mm and 0.2 mm.

22. The flange according to claim 19,
wherein the inner side surface and/or the outer side surface of the cutting edge surrounds/surround the opening in a cone-like manner.

23. The flange according to claim 19,
wherein carbon black is at least partly applied to the cutting edge.

24. The flange according to claim 23,
wherein the carbon black is applied to the outer side surface and the inner side surface is free of carbon black.

25. The flange according to claim 19,
wherein the aluminum alloy used for the flange has a proportion of zinc of 0.15% or less.

26. The flange according to claim 19,
wherein the aluminum alloy used for the flange has a Brinell hardness of 100 HBW or greater.

27. The flange according to claim 19,
wherein the aluminum alloy used for the flange is suitable for a use at temperatures of 140° C or higher.

28. The flange according to claim 19,
wherein the aluminum alloy used for the flange is an Al5xxx alloy.

29. The flange according to claim 19,
wherein the aluminum alloy used for the flange has the following components in addition to aluminum:
Si: a maximum of 0.30%
Fe: a maximum of 0.40%
Cu: 5.8%-6.8%
Mn: 0.20%-0.40%
Mg: a maximum of 0.10%
Cr: a maximum of 0.05%
Zn: a maximum of 0.10%
Ti: 0.02%-0.10%
Further components: a maximum of 0.15%, of which individual components: a maximum of 0.05%

30. A flange connection having a first flange element, a second flange element, a sealing ring and a clamping apparatus,
wherein the first flange element and the second flange element each have a cutting edge for a knife-edge seal,
wherein the sealing ring consists of a softer material than the cutting edges and can be arranged between the first flange element and the second flange element, and the first flange element and the second flange element can be pressed against one another by the clamping apparatus in order to seal the flange connection so that the cutting edge of the first flange element and the cutting edge of the second flange element press into the sealing ring from opposite sides,
wherein the first flange element and/or the second flange element is/are configured as the flange according to claim 19.

31. The flange connection according to claim 30,
wherein the sealing ring consists of an aluminum alloy.

32. The flange connection according to claim 30,
wherein the first flange element is configured as a flange and wherein the second flange element is configured as a cover.

33. A vacuum and/or reaction chamber comprising a chamber wall and an opening in the chamber wall, wherein the vacuum and/or reaction chamber further has a flange for the opening, wherein the flange is arranged in a sealed manner at the opening,
wherein the flange is configured according to claim 19.

34. The vacuum and/or reaction chamber according to claim 33,
wherein the vacuum and/or reaction chamber and the flange are manufactured in one piece and monolithically.

35. The vacuum and/or reaction chamber according to claim 33,
wherein the vacuum and/or reaction chamber has two or more openings in the chamber wall at each of which a flange is arranged.

36. A system for thermal laser epitaxy comprising at least one vacuum and/or reaction chamber, wherein the vacuum and/or reaction chamber has a chamber wall having one or more openings at each of which a flange is arranged,
wherein the vacuum and/or reaction chamber is configured according to claim 33.

37. The flange connection according to claim 31,
wherein the aluminum alloy is EN AW-1050A.
